(19) United States
(12) Patent Application Publication
(10) Pub. No.: US 2025/0329558 A1
(43) Pub. Date: Oct. 23, 2025

(54) PROTECTIVE COMPONENT FORMATION APPARATUS, PROTECTIVE COMPONENT FORMATION METHOD, AND METHOD OF MANUFACTURING WAFER

(71) Applicant: DISCO CORPORATION, Tokyo (JP)

(72) Inventor: Daisuke HIROUCHI, Tokyo (JP)

(21) Appl. No.: 19/171,596

(22) Filed: Apr. 7, 2025

(30) Foreign Application Priority Data
Apr. 23, 2024 (JP) 2024-069901

(51) Int. Cl. H01L 21/67; B24B 7/22; H01L 21/683

(52) U.S. Cl. CPC H01L 21/6715; B24B 7/228; H01L 21/6835; H01L 2221/68327; H01L 2221/68386

(57) ABSTRACT

A protective component formation apparatus includes: a spreading table; a holding table which holds a wafer; a first supplier configured to supply first liquid resin; a second supplier configured to supply second liquid resin having a lower bonding force than the first liquid resin; an elevation mechanism which is configured to spread the liquid resin by moving up and down the holding table and the spreading table relative to each other in a vertical direction; a curer which is configured to cure the liquid resin having been spread; and a controller which is configured to supply the second liquid resin to a central part of the first liquid resin, to spread the first liquid resin and the second liquid resin over the of one surface of the wafer by the elevation mechanism and to cure the first liquid resin and the second liquid resin by the curer.

### CROSS-REFERENCE TO RELATED APPLICATION

This application claims priority from Japanese Patent Application No. 2024-69901 filed with the Japan Patent Office on Apr. 23, 2024, the entire content of which is hereby incorporated by reference.

### BACKGROUND ART

### 1. Technical Field

The present invention relates to a protective component formation apparatus and a protective component formation method for forming a protective component over one surface of a wafer, and to a method of manufacturing a wafer.

### 2. Related Art

For example, a wafer used for manufacturing a semiconductor device such as an IC and an LSI used in an electronic equipment is obtained in a manner described below. To begin with, a sliced wafer is cut out from an ingot made of single crystal of silicon, etc. by using a cutter such as a blade saw or a wire saw. The both surfaces of this sliced wafer are planarized by a grinding apparatus or a polishing apparatus. On one of the planarized surfaces of the wafer, devices such as an IC or an LSI are formed. The other surface of the wafer on which the devices are formed is ground so that the thickness of the wafer is thinned to a predetermined thickness. The thinned wafer is cut by an apparatus such as a dicing saw into each device.

The sliced wafer cut out from the ingot has warps due to a difference in size between process-induced strains formed on the both surfaces at the time of cutting by a cutter such as a blade saw and waviness formed in surface layers of the both surfaces. Due to this, the following processing method has been performed. A protective component made of a material such as UV-curing resin is formed on one surface of a sliced wafer, and the one surface is planarized. While this planarized one surface of the protective component is held by a holding surface of a chuck table, the other surface of the sliced wafer is planarized by grinding. Thereafter, the protective component is peeled off from the sliced wafer, and while the planarized other surface is held by the holding surface of the chuck table, the one surface of the sliced wafer is planarized by grinding. A protective component formation apparatus configured to form a protective component on one surface of a sliced wafer is proposed in, for example, each of Japanese Unexamined Patent Publication No. 2014-192473, Japanese Unexamined Patent Publication No. 2017-079291, and Japanese Unexamined Patent Publication No. 2019-029543.

The protective component formation apparatus forms a protective component by spreading liquid resin over the entirety of one surface of a sliced wafer (hereinafter, this will be simply referred to as wafer) and curing the liquid resin. When spreading the liquid resin over the entirety of one surface of the wafer, the following processes are performed. A sheet is provided on a spreading table, and liquid resin is dropped onto this sheet. A holding table provided above the spreading table is descended to a predetermined height position having been set, together with the wafer held by the holding table. As the liquid resin on the sheet is pressed by the wafer, the liquid resin spreads. When the liquid resin is UV-curing resin, the UV-curing resin is cured by applying UV light to the UV-curing resin.

### SUMMARY

As described above, the wafer in which the protective component is formed over the entirety of one surface is held on the chuck table with the protective component facing down, and the other surface of the wafer is ground by a grinding stone. This grinding involves the following problem: due to the occurrence of peel off of the protective component at an outer circumferential part of the wafer, the outer circumferential part of the wafer is thinned.

In order to solve this problem, the bonding force of the protective component may be increased. However, when the bonding force of the protective component is increased, it becomes difficult to peel the protective component off from the wafer after the grinding. If the protective component is forcibly peeled off, part of the protective component disadvantageously remains on the wafer, or the wafer is damaged.

The present invention has been done to solve the problem above, and objects of the present invention is to provide a protective component formation apparatus and a protective component formation method which suppress a protective component from being peeled off from a wafer during grinding of the wafer and allow the protective component to be easily peeled off from the wafer after the grinding, and to provide a method of manufacturing a wafer which is less warped and waved and has substantially uniform thickness.

A protective component formation apparatus (present protective component formation apparatus) according to an aspect of the present invention includes: a spreading table on which dropped liquid resin is spread; a holding table which is provided above the spreading table to oppose the spreading table and holds a wafer; a liquid resin supplier which is configured to supply the liquid resin to the spreading table side and includes a first supplier configured to supply first liquid resin and a second supplier configured to supply second liquid resin having a lower bonding force than the first liquid resin; an elevation mechanism which is configured to spread the liquid resin by moving up and down the holding table and the spreading table relative to each other in a vertical direction; a curer which is configured to cure the liquid resin having been spread; and a controller which is configured to supply the second liquid resin by the second supplier to a central part of the first liquid resin at least after the first liquid resin is supplied by the first supplier, to spread the first liquid resin and the second liquid resin over one surface of the wafer by the elevation mechanism, to cure the first liquid resin and the second liquid resin by the curer, to bond second resin that is the cured second liquid resin to a central part of the one surface of the wafer to be circular in shape, and to bond first resin that is the cured first liquid resin to a part outside the second resin.

A protective component formation method (present protective component formation method) according to an aspect of the present invention includes a step of forming a protective component by spreading the liquid resin over the one surface of the wafer by using the present protective component formation apparatus, and the step of forming the protective component includes at least: a first liquid resin supplying step of supplying the first liquid resin to the spreading table side; a second liquid resin supplying step of supplying the second liquid resin to a central part of the first liquid resin; a spreading step of spreading the first liquid resin and the second liquid resin over the one surface of the wafer by moving the spreading table and the holding table toward each other in a relative manner in the vertical direction; and a curing step of curing the first liquid resin and the second liquid resin.

A method of manufacturing a wafer of the present invention includes: a protective component formation step of forming the protective component on the one surface of the wafer by the present protective component formation method; a first grinding step of grinding, by a grinding stone, the other surface of the wafer which is opposite to the one surface on which the protective component is formed; a protective component peeling step of peeling the protective component off from the one surface of the wafer; and a second grinding step of grinding, by the grinding stone, the one surface of the wafer from which the protective component has been peeled off.

According to the present protective component formation method executed by using the present protective component formation apparatus, the protective component includes the first resin having a high bonding force and the second resin having a lower bonding force than the first resin. The first resin having the high bonding force is bonded to the outer circumferential part of the one surface of the wafer, and the second resin having the low bonding force is bonded to the inside of the outer circumferential part. It is therefore possible to suppress the first resin having the high bonding force from being peeled off from the outer circumferential part of the wafer, when the wafer is ground. In addition to this, to the most part of the wafer excluding the outer circumferential part, the second resin of the protective component P is bonded. It is therefore possible to easily peel the protective component off from the wafer after the grinding. On this account, it is possible to suppress part of the protective component from remaining on the wafer, and to suppress the wafer from being damaged.

According to the method of manufacturing the wafer of the present invention, the wafer is held on the chuck table, with the one surface of the wafer, which is provided with the protective component and is flat, facing down. In this state, the other surface of the wafer is ground by the grinding stone to be flat. Thereafter, the protective component is peeled off and removed from the one surface of the wafer. Subsequently, the wafer is held on the chuck table with the other surface which is flat facing down, and the one surface of the wafer is ground by the grinding stone. In this way, it is possible to manufacture the wafer which is less warped and waved and has substantially uniform thickness.

### BRIEF DESCRIPTION OF THE DRAWINGS

FIG. 1 is an oblique perspective view of a protective component formation apparatus of the present invention.

FIG. 2 is a vertical cross-sectional view of an important part (i.e., a part including a spreading table and a holding table) of the protective component formation apparatus of the present invention.

FIG. 3 is a vertical cross-sectional view showing a sheet providing step of a protective component formation method of First Embodiment of the present invention.

FIG. 4 is a vertical cross-sectional view showing a first liquid resin supplying step of the protective component formation method of First Embodiment of the present invention.

Each of FIG. 5A and FIG. 5B is a vertical cross-sectional view showing a second liquid resin supplying step of the protective component formation method of First Embodiment of the present invention.

FIG. 6 is a vertical cross-sectional view showing a spreading step of the protective component formation method of First Embodiment of the present invention.

FIG. 7 is a vertical cross-sectional view showing a leaving-alone step of the protective component formation method of First Embodiment of the present invention.

FIG. 8 is a vertical cross-sectional view showing a curing step of the protective component formation method of First Embodiment of the present invention.

FIG. 9 is an enlarged detailed view shown in a part A in FIG. 8.

FIG. 10 is a vertical cross-sectional view showing a state in which a wafer in which a protective component is formed on one surface is ground at the other surface.

FIG. 11 is a side cross-sectional view showing a method of peeling off a protective component.

FIG. 12 is a vertical cross-sectional view showing a state of grinding one surface of a wafer from which a protective component has been peeled off.

Each of FIG. 13A and FIG. 13B is a vertical cross-sectional view showing a second resin supplying step of a protective component formation method of Second Embodiment of the present invention.

FIG. 14 is a vertical cross-sectional view showing a first resin supplying step of the protective component formation method of Second Embodiment of the present invention.

Each of FIG. 15A and FIG. 15B is a vertical cross-sectional view showing a second resin supplying step of the protective component formation method of Second Embodiment of the present invention.

FIG. 16 is a vertical cross-sectional view showing a spreading step of the protective component formation method of Second Embodiment of the present invention.

FIG. 17 is a vertical cross-sectional view showing a leaving-alone step of the protective component formation method of Second Embodiment of the present invention.

FIG. 18 is a vertical cross-sectional view showing a curing step of the protective component formation method of Second Embodiment of the present invention.

### DETAILED DESCRIPTION

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### [Structure of Protective Component Formation Apparatus]

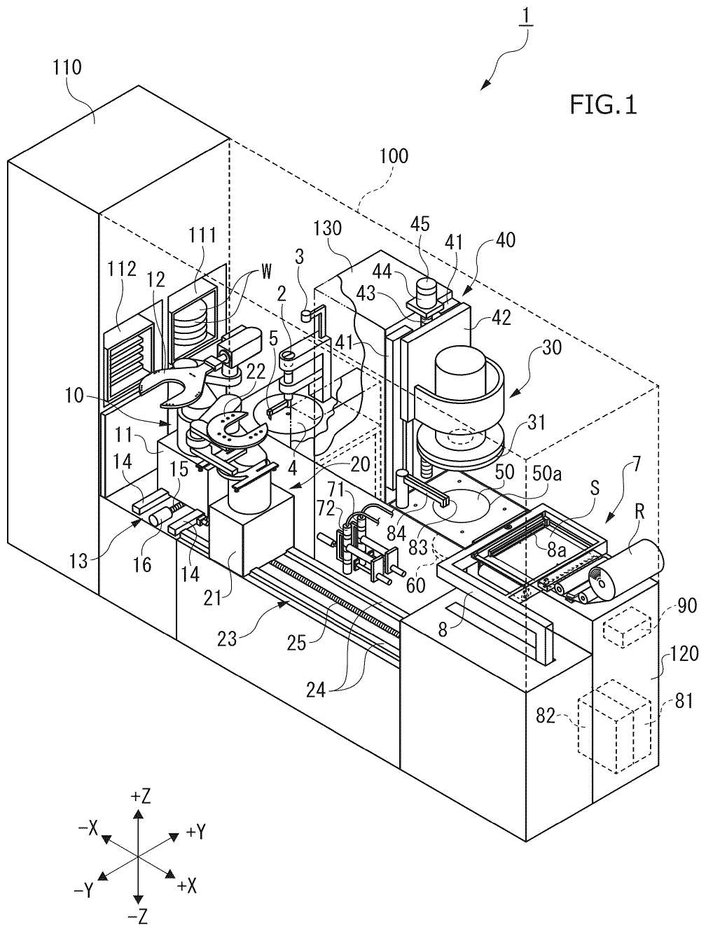

To begin with, the following will describe the structure of a protective component formation apparatus of the present invention with reference to FIG. 1. Hereinafter, the directions indicated by arrows in FIG. 1 are an X-axis direction (left-right direction), a Y-axis direction (front-rear direction), and a Z-axis direction (up-down direction).

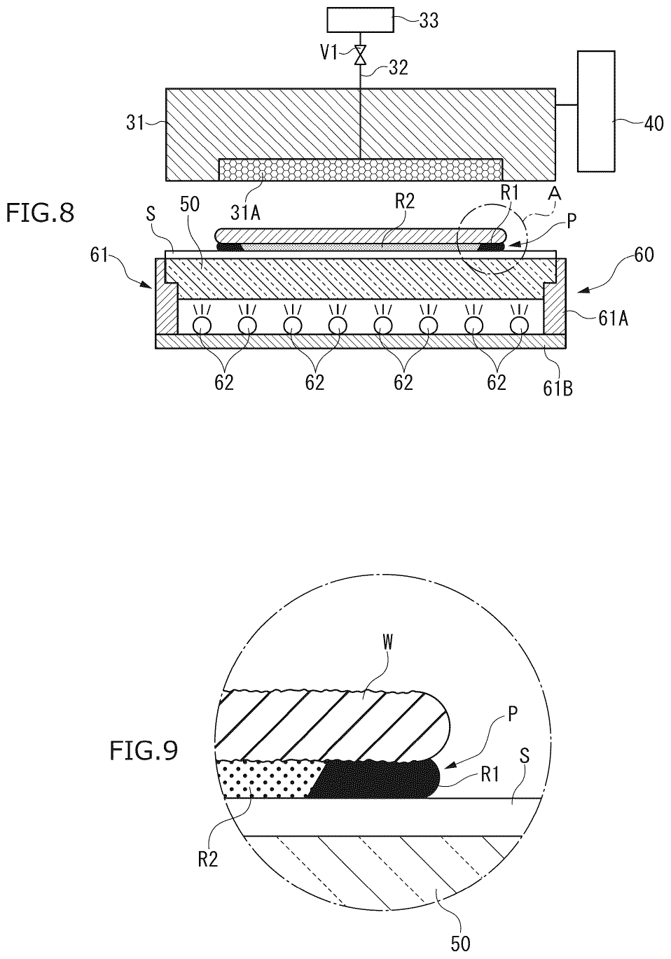

The protective component formation apparatus 1 shown in FIG. 1 is an apparatus configured to form a protective component (protective member) on one surface (bottom surface in FIG. 1) of a disc-shaped wafer W. The protective component formation apparatus 1 includes a housing 100 provided along the X-axis direction and a cassette accommodation 110. The cassette accommodation 110 accommodates a first cassette 111 and a second cassette 112 along the Y-axis direction. The first cassette 111 that is one cassette accommodates wafers W on each of which a later-described protective component P (see FIG. 8 to FIG. 11) has not been formed. The second cassette 112 that is the other cassette accommodates wafers W on each of which the protective component P has already been formed. The wafer W is a disc-shaped sliced wafer which is cut out from a solid cylindrical ingot made of single crystal of silicon, etc.

The housing 100 accommodates elements such as the following elements that are lined up in order from the −X-axis side (left side): a first conveyor 10; a second conveyor 20; a temporary table 2; a sheet cutting table 4; a wafer holder 30; an elevation mechanism 40; a spreading table 50, a curer 60; two dispensers that are a first dispenser 71 and a second dispenser 72; a sheet conveyor 7; and a controller 90. The structure of each element will be described in order.

### (First Conveyor)

The first conveyor 10 is configured to take a wafer W out from the first cassette 111 and convey the wafer W to the temporary table 2, and is configured to receive the wafer W on which the protective component P has been formed from the sheet cutting table 4 and accommodate the received wafer W in the second cassette 112. The first conveyor 10 includes a robot hand 12 which is provided on a pedestal 11 and a Y-axis movement mechanism 13 which is configured to move the pedestal 11 in the Y-axis direction together with the robot hand 12.

The Y-axis movement mechanism 13 includes members such as a pair of guide rails 14 which are provided to be in parallel along the Y-axis direction, a rotatable ball screw 15 which is provided between the guide rails 14 to extend along the Y-axis direction, and a motor 16 which is configured to rotate the ball screw 15 forward and reverse. Into an unillustrated nut protruding from the bottom surface of the pedestal 11, the ball screw 15 is screwed. With this arrangement, as the motor 16 is activated and the ball screw 15 is rotated forward or reverse, the pedestal 11, from which the unillustrated nut into which the ball screw 15 is screwed protrudes, moves along the Y-axis direction together with the robot hand 12.

### (Second Conveyor)

The second conveyor 20 is configured to receive a wafer W from the temporary table 2 and convey the wafer W to the wafer holder 30, and is configured to receive the wafer W on which the protective component P is formed from the spreading table 50 and convey the wafer W to the sheet cutting table 4. The second conveyor 20 includes a robot hand 22 which is provided on a pedestal 21 and an X-axis movement mechanism 23 which is configured to move the pedestal 21 in the X-axis direction together with the robot hand 22.

The X-axis movement mechanism 23 includes members such as a pair of guide rails 24 which are provided to be in parallel along the X-axis direction, a rotatable ball screw 25 which is provided between the guide rails 24 to extend along the X-axis direction, and an unillustrated motor which is configured to rotate the ball screw 25 forward and reverse. Into an unillustrated nut protruding from the bottom surface of the pedestal 21, the ball screw 25 is screwed. With this arrangement, as the unillustrated motor is activated and the ball screw 25 is rotated forward or reverse, the pedestal 21, from which the unillustrated nut into which the ball screw 25 is screwed protrudes, moves along the X-axis direction together with the robot hand 22.

### (Temporary Table)

On the temporary table 2, a wafer W taken out from the first cassette 111 by the robot hand 12 of the first conveyor 10 is temporarily placed. The position of the center and the orientation of the wafer W temporarily placed on the temporary table 2 are optically detected by a wafer detector 3.

### (Sheet Cutting Table)

The sheet cutting table 4 is provided below the temporary table 2. On the sheet cutting table 4, a wafer W on which a protective component P has been formed is placed. A sheet S pasted onto the wafer W is cut to be circular in shape along the outer circumference of the wafer W, by a sheet cutter 5.

### (Wafer Holder)

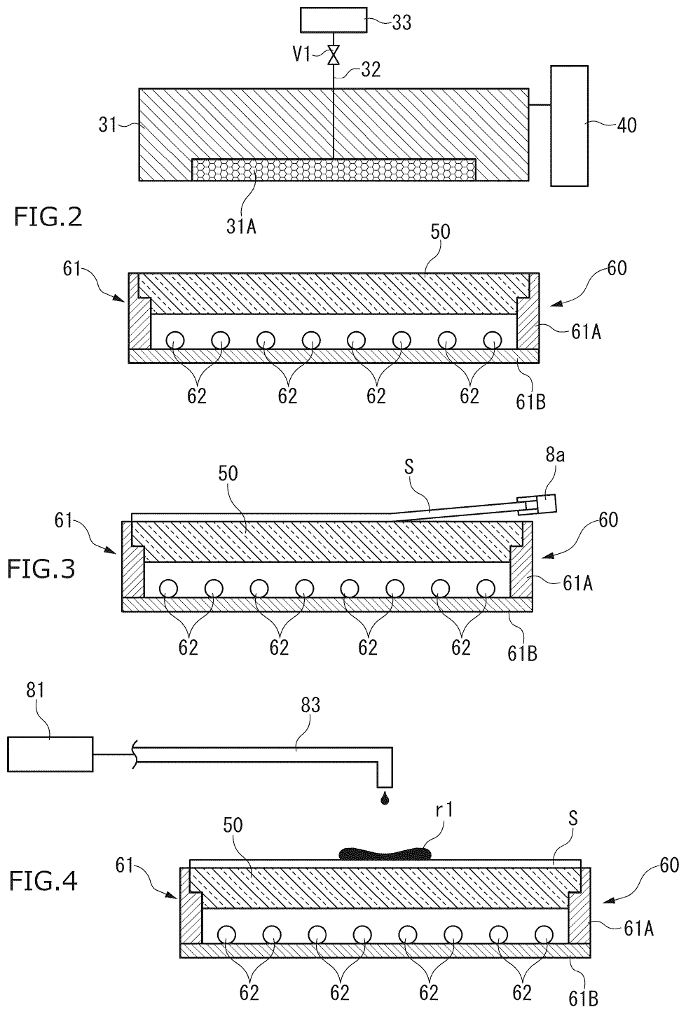

The wafer holder 30 has a disc-shaped holding table 31. The bottom surface of the holding table 31 constitutes a holding surface. In this connection, as shown in FIG. 2, a disc-shaped porous member 31A that is porous is embedded in a central portion of a lower portion of the holding table 31. This porous member 31A is selectively connected to a suction source 33 such as a vacuum pump through a pipe 32. The pipe 32 is provided with a shut-off valve V1.

### (Elevation Mechanism)

The elevation mechanism 40 is configured to move up and down the holding table 31 of the wafer holder 30 in the Z-axis direction together with the wafer W which is sucked and held by the holding table 31. The elevation mechanism 40 is provided on a column 130 which perpendicularly stands up on the base 120. That is to say, the elevation mechanism 40 includes: a pair of guide rails 41 which are attached to an end face on the +x-axis side of the column 130 to extend in the Z-axis direction and are in parallel to each other; an elevation plate 42 which moves up and down in the Z-axis direction along the guide rails 41; a rotatable ball screw 43 which is orthogonally provided between the pair of guide rails 41; a motor 44 which is configured to rotate the ball screw 43 forward and reverse; and an encoder 45 which is configured to detect the number of rotations, the rotation speed, the rotational direction, etc. of the motor 44.

To the elevation plate 42, the holding table 31 of the wafer holder 30 is attached. The encoder 45 constitutes a position detector configured to detect the height position of the holding table 31 based on the number of rotations and the rotational direction of the motor 44. The encoder 45 and the motor 44 are electrically connected to the controller 90. Although not illustrated, a nut is attached to the back surface of the elevation plate 42. Into this nut, the ball screw 43 is inserted and screwed.

With this arrangement, as the motor 44 is activated and the ball screw 43 is rotated forward or reverse, the elevation plate 42 to which the unillustrated nut to which the ball screw 43 is screwed is attached is moved up or down in the Z-axis direction along the pair of guide rails 41, together with the wafer holder 30 and the wafer W sucked and held by the holding table 31 of the wafer holder 30. At this stage, the height position of the holding table 31 is detected by the encoder 45 that is the position detector.

### (Spreading Table)

The spreading table 50 provided on the base 120 is a disc-shaped member made of a translucent material such as quartz glass. The top surface of the spreading table 50 constitutes a flat holding surface on which a sheet S is mounted. Around the holding surface of the spreading table 50, a ring-shaped sucking groove 50a is formed.

### (Curer)

The curer 60 is provided below the spreading table 50. As described below, the curer 60 is configured to apply ultraviolet (UV) light to first liquid resin r1 (see FIG. 4) and second liquid resin r2 (see FIG. 5) which are UV-curing resin supplied to the sheet S mounted on the spreading table 50, so as to cure the first liquid resin r1 and the second liquid resin r2. As shown in FIG. 2, the curer 60 has a casing 61 whose top is closed by the spreading table 50. The casing 61 includes side walls 61A and a bottom plate 61B. In the space defined by the side walls 61A, the bottom plate 61B, and the spreading table 50, UV lamps 62 configured to apply ultraviolet light to the first liquid resin r1 and the second liquid resin r2 are accommodated.

### (Dispensers)

The first dispenser 71 is configured to supply, each time by a predetermined amount, the first liquid resin r1 stored in a first resin tank 81 provided in the base 120 to the top surface of the sheet S held on the top surface of the spreading table 50. The second dispenser 72 is configured to supply, each time by a predetermined amount, the second liquid resin r2 stored in a second resin tank 82 provided in the base 120 to the top surface of the sheet S held on the top surface of the spreading table 50. The first dispenser 71 is connected to the first resin tank 81 and a first resin nozzle 83 through an unillustrated resin pipe. The second dispenser 72 is connected to the second resin tank 82 and a second resin nozzle 84 through an unillustrated resin pipe.

Members such as the first dispenser 71, the first resin tank 81, and the first resin nozzle 83 constitute a first supplier which is configured to supply the first liquid resin r1 to the sheet S. Members such as the second dispenser 72, the second resin tank 82, and the second resin nozzle 84 constitute a second supplier which is configured to supply the second liquid resin r2 to the sheet S.

### (Sheet Conveyor)

The sheet conveyor 7 is configured to draw a sheet S out from a sheet roll R formed by winding and rolling sheets S, and to convey the drawn sheet S to the spreading table 50. The sheet conveyor 7 includes an arm 8 movable in the X-axis direction and a clamp portion 8a attached to a side portion of the arm 8. With this arrangement, when the arm 8 moves in the −X-axis direction while the clamp portion 8a grips an end portion of a sheet S wound on the sheet roll R, the sheet S is drawn out from the sheet roll R and the sheet S is held by the top surface of the spreading table 50. The sheet S held by the spreading table 50 is cut into a suitable length. The sheet S is a film made of, for example, polyethylene terephthalate (PET) that is a translucent material allowing ultraviolet light to pass through. In this regard, when the liquid resin is thermosetting, the sheet S may not be made of the translucent material.

### (Controller)

The controller 90 includes members such as a CPU (Central Processing Unit) configured to perform computation based on a control program and a storage such as a ROM (Read Only Memory) and/or a RAM (Random Access Memory). In particular, in the present embodiment, as described below, the controller 90 controls the above-described elements, so as to form a protective component P on one surface of a wafer W (for example, the entirety of the one surface of the wafer W) by supplying first liquid resin r1 and second liquid resin r2 to a surface of a sheet S, spreading the first liquid resin r1 and the second liquid resin r2 on the one surface of the wafer W (for example, the entirety of the one surface of the wafer W), and curing the first liquid resin r1 and the second liquid resin r2 which have been spread.

### [Protective Component Formation Method]

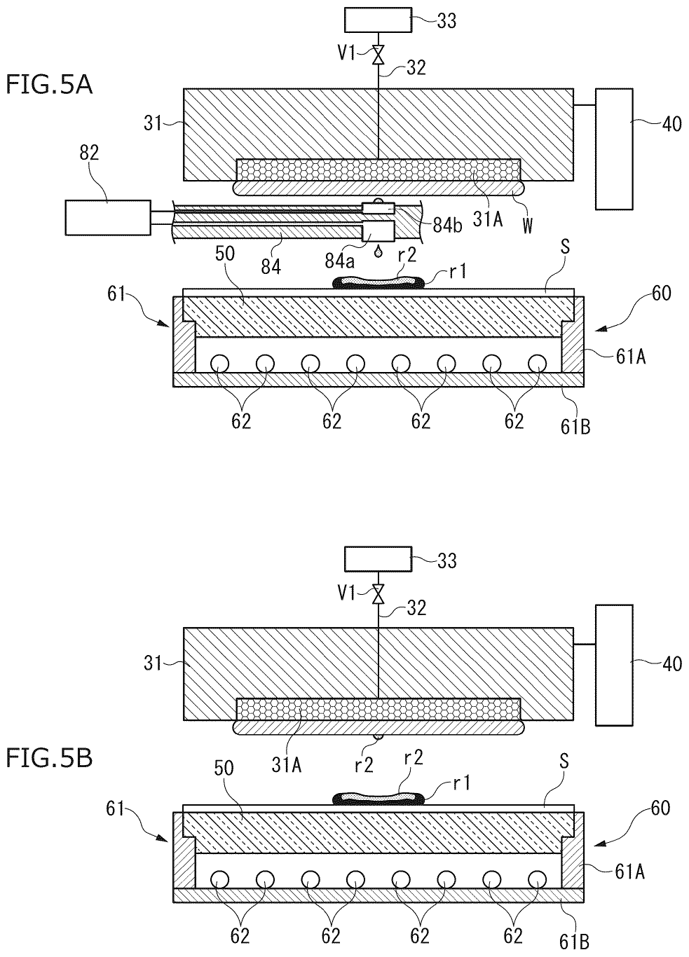

The following will describe a protective component formation method of the present invention, which is executed by using the protective component formation apparatus 1 arranged as described above, with reference to FIG. 3 to FIG. 9.

### First Embodiment

In a protective component formation method of First Embodiment, the following steps are performed in this order:
1) a sheet providing step;
2) a first liquid resin supplying step;
3) a second liquid resin supplying step;
4) a spreading step;
5) leaving-alone step; and
6) curing step.

As a result of performing these steps, a protective component P is formed on one surface of a wafer W (for example, the entirety of the one surface of the wafer W). Each step will be described one by one.

### 1) Sheet Providing Step

In the sheet providing step, as shown in FIG. 3, a rectangular sheet S that is thin and transparent is provided on the spreading table 50 provided on the top surface of the casing 61 of the curer 60. To put it differently, in a state in which an end of a sheet S wound onto a sheet roll R is gripped by the clamp portion 8a of the arm 8 of the sheet conveyor 7 shown in FIG. 1, the arm 8 moves in the −X-axis direction shown in FIG. 1, with the result that the sheet S is supplied to and set on the spreading table 50.

### 2) First Liquid Resin Supplying Step

In the first liquid resin supplying step, the first liquid resin r1 stored in the first resin tank 81 shown in FIG. 1 is supplied to the first resin nozzle 83 by the first dispenser 71. Furthermore, as shown in FIG. 4, the first resin nozzle 83 drops the first liquid resin r1 toward a central part of the sheet S. As the first liquid resin r1 is dropped onto the central part of the sheet S, the dropped first liquid resin r1 spreads in the form of a circle having a short diameter, at the central part of the sheet S. At a central part of the circular first liquid resin r1, a concave is formed.

### 3) Second Liquid Resin Supplying Step

In the second liquid resin supplying step, a second liquid resin r2 stored in the second resin tank 82 shown in FIG. 1 is supplied to the second resin nozzle 84 by the second dispenser 72 shown in FIG. 1. Furthermore, as shown in FIG. 5A, the first nozzle 84a of the second resin nozzle 84 drops the second liquid resin r2 toward a central part of the sheet S. Thereafter, the nozzle 84b that is open upward supplies a small amount of the second liquid resin r2 to a central part of one surface (bottom surface in FIG. 5A) of a wafer W sucked and held by the bottom surface of the holding table 31. Resin used as the second liquid resin r2 has a lower adhesive strength than the first liquid resin r1. In the present embodiment, as the first liquid resin r1 and the second liquid resin r2, alternative liquid resin such as thermosetting resin may be used in place of the UV-curing resin.

In this second liquid resin supplying step, as shown in FIG. 5B, a predetermined amount of the second liquid resin r2 is dropped in an overlapping manner to the central part of the first liquid resin r1 having already been dropped to the central part of the sheet S provided on the spreading table 50. Furthermore, a small amount of the second liquid resin r2 is supplied to a central part of one surface (bottom surface in FIG. 5B) of the wafer W held by the holding table 31.

In this connection, as described above, as the second liquid resin r2 is dropped in an overlapping manner to the central part of the first liquid resin r1 having already been dropped onto the sheet S, the central parts of the first liquid resin r1 and the second liquid resin r2 are dented. In the later-described spreading step, the shortage of the second liquid resin r2 at the dent at the central parts of the first liquid resin r1 and the second liquid resin r2 on the sheet S is made up by a small amount of the second liquid resin r2 adhered to the central part of the one surface (bottom surface) of the wafer W.

### 4) Spreading Step

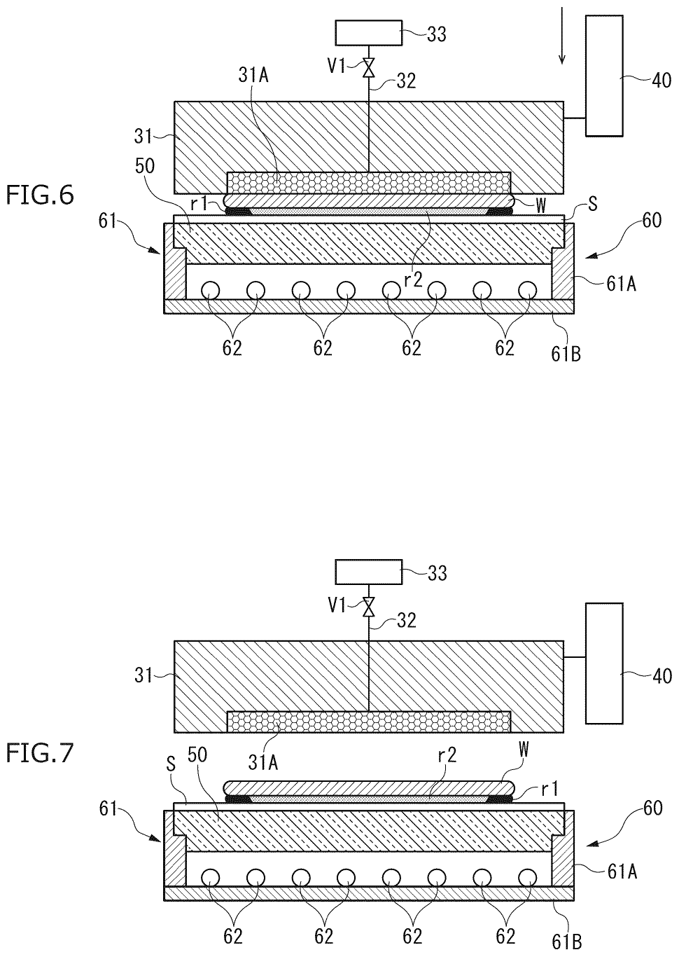

In the spreading step, as shown in FIG. 6, the first liquid resin r1 and the second liquid resin r2 dropped onto the sheet S in the first liquid resin supplying step and the second liquid resin supplying step are spread (expanded) on the one surface of the wafer W (for example, the entirety of the one surface of the wafer W). In this spreading step, the shut-off valve V1 is opened and the porous member 31A of the holding table 31 is connected to the suction source 33 through the pipe 32. Due to this, a negative pressure is generated at the porous member 31A, and the wafer W drawn by this negative pressure is sucked and held by the holding surface of the holding table 31 (i.e., the bottom surface of the porous member 31A).

As the holding table 31 in this state is moved down by the elevation mechanism 40, the wafer W sucked and held by the bottom surface of the holding table 31 presses the first liquid resin r1 and the second liquid resin r2 on the sheet S, with the result that the first liquid resin r1 and the second liquid resin r2 are spread to have a uniform thickness. In this spreading step, as described above, the shortage of the second liquid resin r2 at the dent of the second liquid resin r2 which has been dropped to the central part of the sheet S in the second liquid resin supplying step and has the dent at its central part is made up by a small amount of the second liquid resin r2 supplied to and adhered to the central part of the wafer W.

Thereafter, as described above, the first liquid resin r1 on the sheet S and the second liquid resin r2 superposed on the resin r1 are spread by the descending wafer W. As a result, the first liquid resin r1 and the second liquid resin r2 are spread to have a circular shape and a uniform thickness. At this stage, the outer circumferential part of the circular resin is constituted by the ring-shaped first liquid resin r1 having a high bonding force. Inside the ring-shaped first liquid resin r1, the second liquid resin r2 having a low bonding force is provided to be circular in shape.

### 5) Leaving-Alone Step

In the spreading step that is a preceding step of the leaving-alone step, the first liquid resin r1 and the second liquid resin r2 are spread by one surface (bottom surface) of the wafer W, as described above. As shown in FIG. 7, in the leaving-alone step, the shut-off valve V1 is opened, the porous member 31A and the suction source 33 are disconnected from each other, and hence the sucking holding force exerted by the holding table 31 disappears. Furthermore, the holding table 31 is moved up by the elevation mechanism 40 and leaves the wafer W. As a result, the load acting on the first liquid resin r1 and the second liquid resin r2 having been spread to be circular by the one surface (bottom surface) of the wafer W becomes only the own weight of the wafer W. Due to this, the first liquid resin r1 and the second liquid resin r2 become no longer flow, and the state in which the first liquid resin r1 and the second liquid resin r2 are spread to reach the outer circumferential edge of the wafer W is maintained.

### 6) Curing Step

In the leaving-alone step that is a preceding step of the curing step, the first liquid resin r1 and the second liquid resin r2 which are spread to be circular by the one surface (bottom surface) of the wafer W become no longer flow, and support the wafer W. In the curing step, as shown in FIG. 8, the UV lamps 62 in the casing 61 are turned on. As a result, ultraviolet (UV) light emitted upward from each UV lamp 62 passes through the transparent spreading table 50 and the transparent sheet S and reaches the first liquid resin r1 and the second liquid resin r2. Due to this, the first liquid resin r1 and the second liquid resin r2 are cured by the applied ultraviolet light, and become first resin R1 and second resin R2. Consequently, a protective component P including the first resin R1 and the second resin R2 is formed on the one surface (bottom surface in FIG. 8, for example, the entirety of the one surface) of the wafer W (protective component formation step).

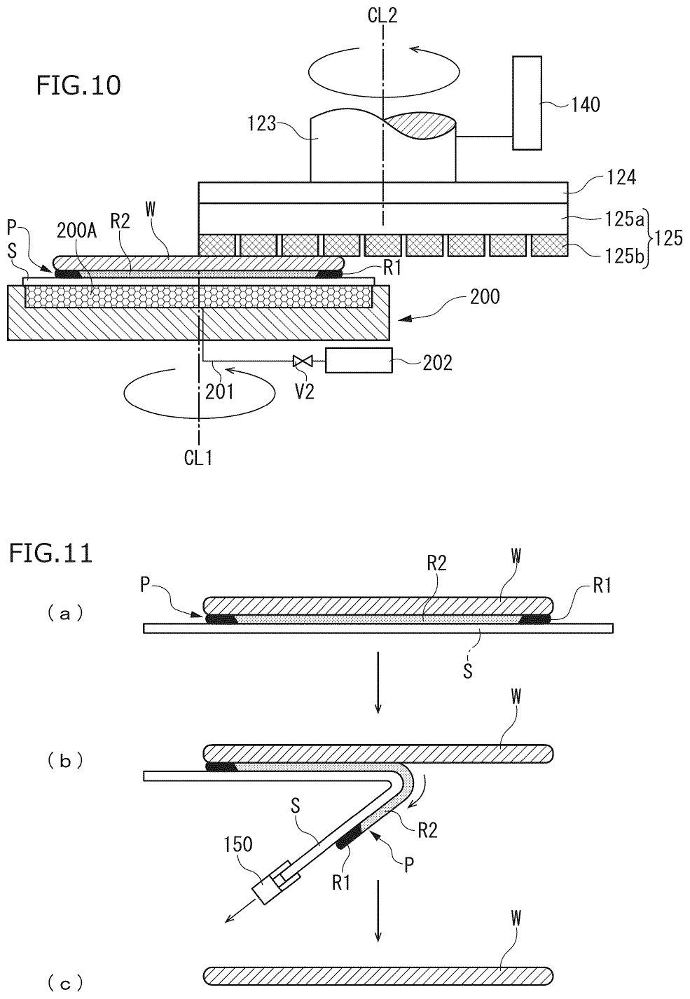

Through the above-described steps, the protective component P is formed on the one surface of the wafer W. Thereafter, the other surface (i.e., the surface where the protective component P is not formed) of the wafer W is ground by grinding stones 125b of a grinding apparatus shown in FIG. 10 (first grinding step). A spindle 123 shown in FIG. 10 is rotationally driven by an unillustrated spindle motor. To the lower end of the spindle 123, a disc-shaped mount is attached. To the bottom surface of the mount 124, a grinding wheel 125 is detachably attached. This grinding wheel 125 includes a disc-shaped base 125a and the grinding stones 125b provided on and attached to the bottom surface of the base 125a to be ring-shaped. A grinding unit including the grinding wheel 125 can be moved up and down in the vertical direction by an elevation mechanism 140.

When the other surface (where the protective component P is not formed) of the wafer W on which the protective component P is formed on the one surface is ground, as shown in FIG. 10, the wafer W is sucked and held by a holding surface of a chuck table 200, with the flat protective component P facing down. In this connection, a disc-shaped porous member 100A that is porous is embedded in a central portion of an upper portion of the chuck table 200. This porous member 200A is connected to a suction source 202 through a pipe 201. The pipe 201 is provided with a shut-off valve V2.

Due to this, as the shut-off valve V2 is opened and the porous member 200A is connected to the suction source 202, a negative pressure is generated in the porous member 200A, with the result that the wafer W is drawn by the negative pressure and is sucked and held by the holding surface (top surface) of the chuck table 200, with the sheet S (protective component P) facing down. The chuck table 200 is arranged to be rotatable about a rotational axial center CLI which extends perpendicularly. The chuck table 200 is rotationally driven at a predetermined speed in a direction indicated by an arrow in FIG. 10, by an unillustrated drive source.

The grinding wheel 125 is rotationally driven at a predetermined speed in a direction indicated by an arrow in the figure (in the same direction as the rotational direction of the chuck table 200) about a rotational axial center CL2 of the spindle 123, by an unillustrated spindle motor. The grinding wheel 125 is moved up and down in the vertical direction by the elevation mechanism 140.

When the wafer W is ground, the chuck table 200 is rotationally driven together with the wafer W at a predetermined speed in the direction indicated by the arrow in the figure, about the rotational axial center CL1 by an unillustrated rotating mechanism. While the circumscribed circle of the grinding stones 125b is positioned to pass through the center of the wafer W, the grinding wheel 125 is rotationally driven at a predetermined speed about the rotational axial center CL2 by the unillustrated spindle motor.

In the state described above, the grinding wheel 125 is moved down by the elevation mechanism 140 by a predetermined grinding length. As a result, the other surface (top surface shown in FIG. 10) of the wafer W, where the protective component P is not formed, is ground by the grinding stones 125b. Consequently, the warpage and wave remaining on the other surface of the wafer W are removed, and hence the other surface (top surface in FIG. 10) of the wafer W becomes a flat surface. When the wafer W is ground, grinding water (pure water) is supplied to a contact point (processing point) between the wafer W and each grinding stone 125b. On this account, the frictional heat generated at the processing point is removed by the grinding water, and temperature increase at the processing point is suppressed. Furthermore, grinding chips generated by the grinding are washed away by the grinding water.

In the above-described grinding of the wafer W, the protective component P includes the first resin R1 having a high bonding force and the second resin R2 having a lower bonding force than the first resin R1. The first resin R1 having the high bonding force is bonded to the outer circumferential part of the one surface of the wafer W, and the second resin R2 having the low bonding force bonded to the inside of the outer circumferential part. It is therefore possible to suppress the first resin R1 having the high bonding force from being peeled off from the outer circumferential part of the wafer W, when the wafer W is ground.

As described above, the other surface of the wafer W is ground to be a flat surface. Thereafter, the protective component P formed on the one surface of the wafer W is peeled off from the wafer W together with the sheet S, in a manner described below (protective component peeling step).

As a method of peeling the protective component off from the wafer W together with the sheet S, the following method is employed in the present embodiment; the protective component P is peeled off by applying a force to the protective component P in a direction in which the protective component P is easily peeled off. According to this method, as shown in (a) in FIG. 11, a protective component P has been formed on one surface (bottom surface in (a) in FIG. 11) of a wafer W in which the other surface has been ground by grinding. As shown in (b) in FIG. 11, an end portion of a sheet S of this protective component P is held by a clamper 150, and the clamper 150 is pulled in an arrow direction (obliquely downward) in which the protective component P is easily peeled off, so that the protective component P is peeled off from the wafer W. The wafer W from which the protective component P has been peeled off in this way is shown in (c) in FIG. 11. On the one surface (bottom surface in (c) in FIG. 11) of the wafer W, from which the protective component P has been peed off, a warp and/or a wave still exists.

In regard to the above, in the present embodiment, the protective component P includes the first resin RI having a high bonding force and the second resin R2 having a lower bonding force than the first resin R1. The first resin RI having the high bonding force is bonded to the outer circumferential part of the one surface of the wafer W. The second resin R2 having the low bonding force is bonded to the inside of the outer circumferential part. In other words, to the most part of the wafer W excluding the outer circumferential part, the second resin R2 is bonded. It is therefore possible to easily peel the protective component P off from the wafer W, together with the sheet S.

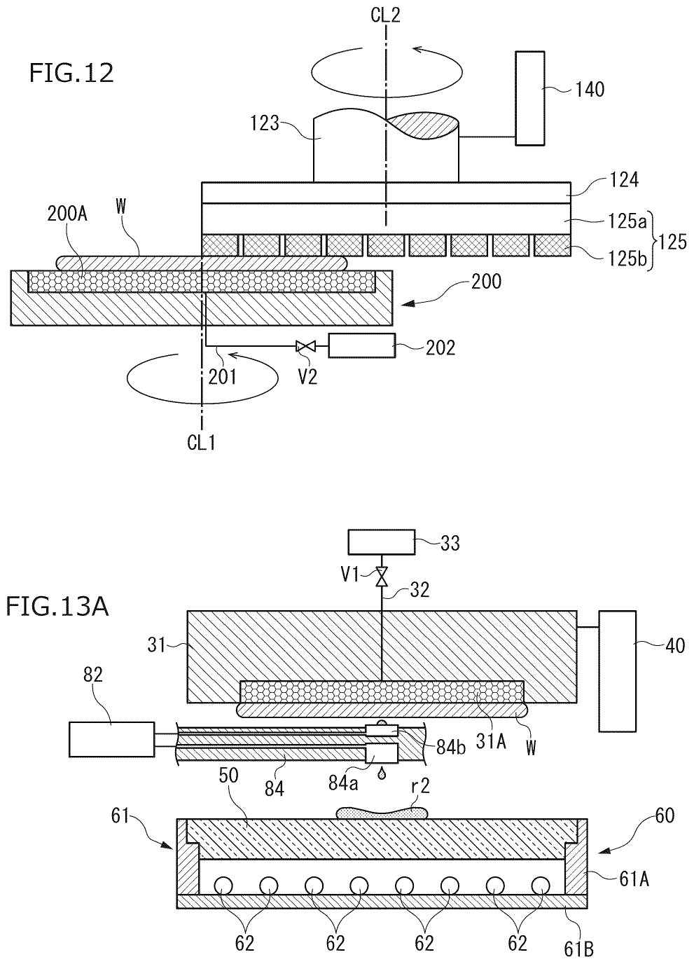

As described above, the protective component P is peeled off from the wafer W together with the sheet S. Thereafter, as shown in FIG. 12, the wafer W is sucked and held by the holding surface of the chuck table 200, with the other surface of the wafer W, which has already been ground to be flat, facing down. Then the one surface of the wafer W, from which the protective component P has been peeled off, is ground by the grinding stones 125b in the same manner as above (second grinding step).

That is to say, as shown in FIG. 12, the chuck table 200 is rotationally driven together with the wafer W at a predetermined speed in the direction indicated by the arrow in the figure about the rotational axial center CL1 by the unillustrated rotating mechanism. While the circumscribed circle of the grinding stones 125b is positioned to pass through the center of the wafer W, the grinding wheel 125 is rotationally driven at a predetermined speed about the rotational axial center CL2 by the unillustrated spindle motor.

In the state described above, the grinding wheel 125 is moved down by the elevation mechanism 140 by a predetermined grinding length. As a result, the one surface (top surface shown in FIG. 12) of the wafer W, where the protective component P has been formed, is ground by the grinding stones 125b. Consequently, the warpage and wave remaining on the one surface of the wafer W are removed, and hence the both surfaces of the wafer W become flat surfaces. Also in this grinding, grinding water (pure water) is supplied to a contact point (processing point) between the wafer W and each grinding stone 125b. On this account, the frictional heat generated at the processing point is removed by the grinding water, and temperature increase at the processing point is suppressed. Furthermore, grinding chips generated by the grinding are washed away by the grinding water.

As clarified above, in the present embodiment, the protective component P includes the first resin R1 having a high bonding force and the second resin R2 having a lower bonding force than the first resin R1. The first resin R1 having the high bonding force is bonded to the outer circumferential part of the one surface of the wafer W, and the second resin R2 having the low bonding force is bonded to the inside of the outer circumferential part. With this arrangement, the following effects are obtained. It is possible to suppress the first resin R1 having the high bonding force from being peeled off from the outer circumferential part of the wafer W, when the wafer W is ground. In addition to this, to the most part of the wafer W excluding the outer circumferential part, the second resin R2 of the protective component P is bonded. It is therefore possible to easily peel the protective component P off from the wafer W after the grinding. On this account, it is possible to suppress part of the protective component P from remaining on the wafer W, and to suppress the wafer W from being damaged.

Furthermore, according to the present embodiment, the wafer W is held on the chuck table 200, with one surface of the wafer W, which is provided with the protective component P and is flat, facing down. In this state, the other surface of the wafer W is ground by the grinding stones 125b to be flat. Thereafter, the protective component P is peeled off and removed from the one surface of the wafer W. Subsequently, the wafer W is held on the chuck table 200 with the other surface which is flat facing down, and the one surface of the wafer W is ground by the grinding stones 125b. In this way, it is possible to manufacture the wafer W which is less warped and waved and has substantially uniform thickness.

### Second Embodiment

The following will describe a protective component formation method of Second Embodiment of the present invention with reference to FIG. 13 to FIG. 18.

In the protective component formation method of the present embodiment, the following steps are performed in this order:
1) a second liquid resin supplying step for the first time;
2) a first liquid resin supplying step;
3) a second liquid resin supplying step for the second time;
4) a spreading step;
5) leaving-alone step; and
6) curing step.

As a result of performing these steps, a protective component P is formed on one surface of a wafer W (for example, the entirety of the one surface of the wafer W). In this method, the sheet S described in First Embodiment above is not used. According to the method of Second Embodiment, second liquid resin r2 having a low bonding force is dropped onto the spreading table 50, first liquid resin r1 is dropped on the top, and second liquid resin r2 is dropped further on the top. Each step will be described one by one.

### 1) Second Liquid Resin Supplying Step for First Time

In the second liquid resin supplying step, as shown in FIG. 13A and FIG. 13B, the second liquid resin r2 having a low bonding force is dropped from the first nozzle 84a of the second resin nozzle 84 toward a central part of the spreading table 50. Furthermore, the nozzle 84b that is open upward supplies a small amount of the second liquid resin r2 to a central part of one surface of a wafer W (bottom surface of the wafer W in FIG. 13A) sucked and held by the bottom surface of the holding table 31.

### 2) First Liquid Resin Supplying Step

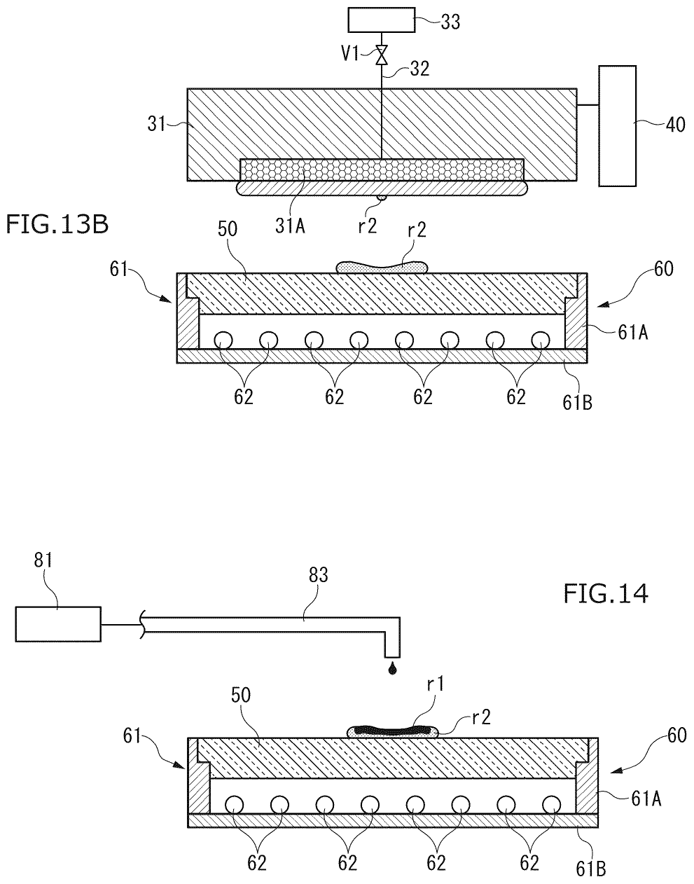

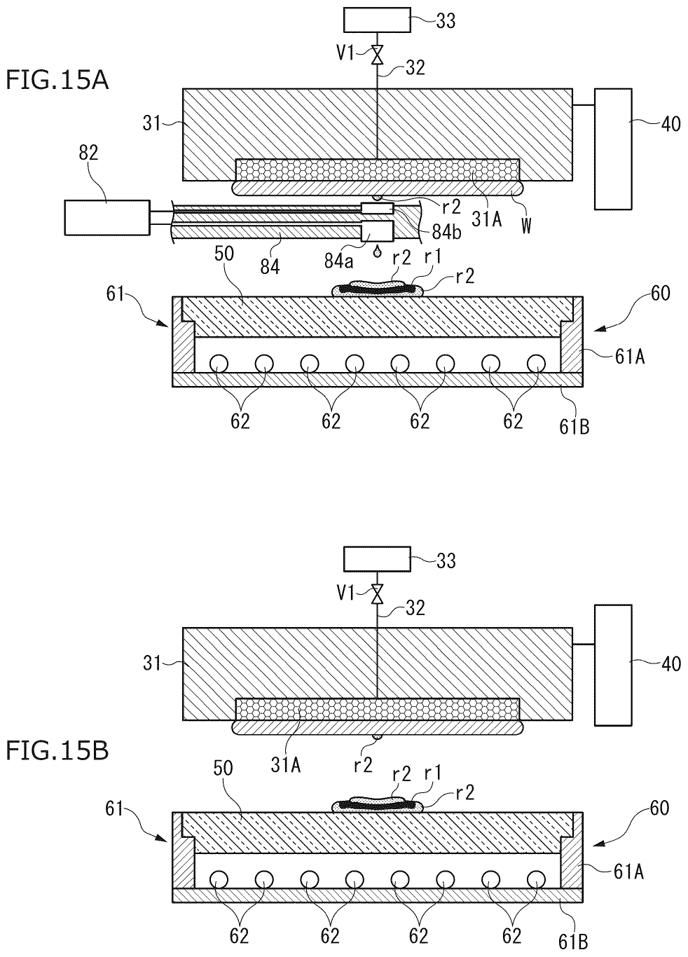

In the first liquid resin supplying step, as shown in FIG. 14, the first liquid resin r1 having a high bonding force is dropped from the first resin nozzle 83 onto the second liquid resin r2 on the spreading table 50 in an overlapping manner.

### 3) Second Liquid Resin Supplying Step for Second Time

In the second liquid resin supplying step, as shown in FIG. 15A, the second liquid resin r2 is dropped from the first nozzle 84a of the second resin nozzle 84 onto the first liquid resin r1 having been dropped to overlap the second liquid resin r2 on the spreading table 50, in an overlapping manner. Furthermore, the nozzle 84b that is open upward may supply a small amount of the second liquid resin r2 to the central part of the one surface (bottom surface in FIG. 15A) of a wafer W sucked and held by the bottom surface of the holding table 31.

In this second liquid resin supplying step, as shown in FIG. 15B, a predetermined amount of the second liquid resin r2 is further dropped in an overlapping manner onto the second liquid resin r2 and the first liquid resin r1 having already been dropped onto the spreading table 50. When a small amount of the second liquid resin r2 is not supplied to the central part of the one surface of the wafer W (bottom surface of the wafer W in FIG. 13A) in the second liquid resin supplying step for the first time, a small amount of the second liquid resin r2 may be supplied in this step.

### 4) Spreading Step

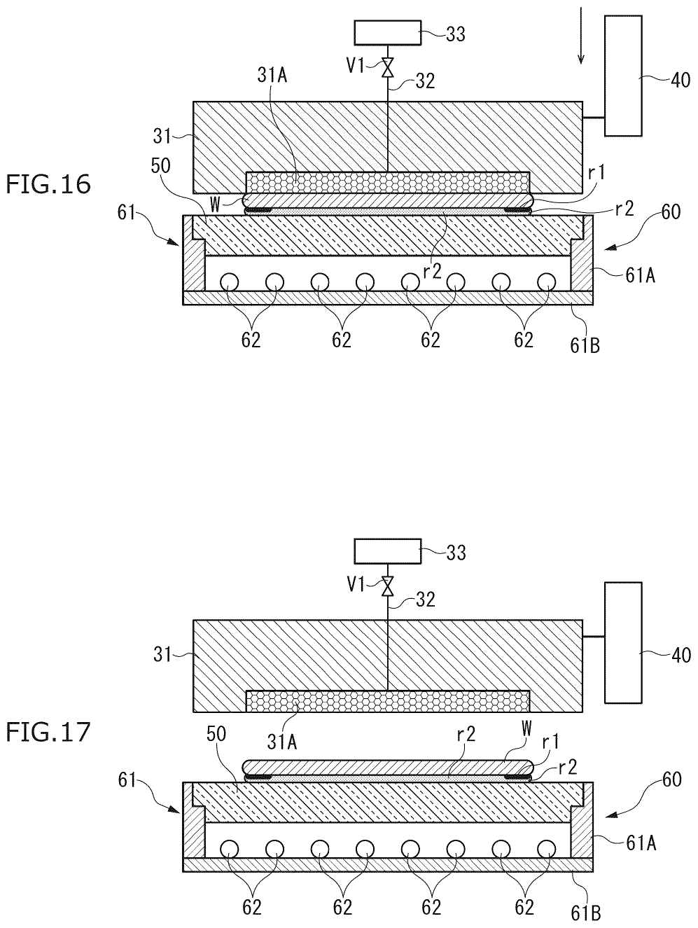

As shown in FIG. 16, the second liquid resin r2, the first liquid resin r1, and the second liquid resin r2 dropped onto the spreading table 50 in the second liquid resin supplying step for the first time, the first liquid resin supplying step, and the second liquid resin supplying step for the second time form a three-layer structure. In the spreading step, the second liquid resin r2, the first liquid resin r1, and the second liquid resin r2 are spread on the one surface of the wafer W (for example, the entirety of the one surface of the wafer W). In this spreading step, the shut-off valve V1 is opened and the porous member 31A of the holding table 31 is connected to the suction source 33 through the pipe 32. Due to this, a negative pressure is generated at the porous member 31A, and the wafer W drawn by this negative pressure is sucked and held by the holding surface of the holding table 31 (i.e., the bottom surface of the porous member 31A).

As the holding table 31 in this state is moved down by the elevation mechanism 40, the wafer W sucked and held by the bottom surface of the holding table 31 presses the second liquid resin r2, the first liquid resin r1, and the second liquid resin r2 forming the three-layer structure on the spreading table 50. As a result of this, the upper layer and the lower layer of the second liquid resin r2 are connected with each other, the second liquid resin r2 is spread at the central part of the wafer W, and the first liquid resin r1 is spread to be ring-shaped by the second liquid resin r2. Furthermore, below the first liquid resin r1, the second liquid resin r2 is spread. As a result, at the outer circumferential part of the wafer W, a two-layer structure including the first liquid resin r1 and the second liquid resin r2 provided below the first liquid resin r1 is formed.

### 5) Leaving-Alone Step

In the spreading step that is a preceding step of the leaving-alone step, the first liquid resin r1 and the second liquid resin r2 are spread by one surface (bottom surface) of the wafer W, as described above. As shown in FIG. 17, in the leaving-alone step, the shut-off valve V1 is opened, the porous member 31A and the suction source 33 are disconnected from each other, and hence the sucking holding force exerted by the holding table 31 disappears. Furthermore, the holding table 31 is moved up by the elevation mechanism 40 and leaves the wafer W. As a result, the load acting on the first liquid resin r1 and the second liquid resin r2 having been spread to be circular by the one surface (bottom surface) of the wafer W becomes only the own weight of the wafer W. Due to this, the first liquid resin r1 and the second liquid resin r2 become no longer flow, and the state in which the first liquid resin r1 and the second liquid resin r2 are spread to reach the outer circumferential edge of the wafer W is maintained.

### 6) Curing Step

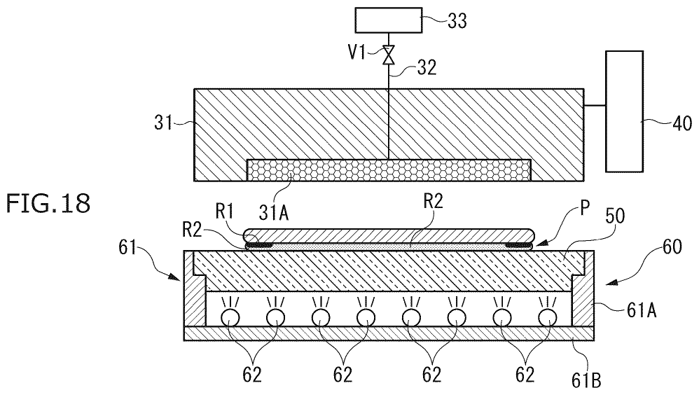

In the leaving-alone step that is a preceding step of the curing step, the first liquid resin r1 and the second liquid resin r2 which are spread to be circular by the one surface (bottom surface) of the wafer W become no longer flow, and support the wafer W. In the curing step, as shown in FIG. 18, the UV lamps 62 in the casing 61 are turned on. As a result, ultraviolet (UV) light emitted upward from each UV lamp 62 passes through the transparent spreading table 50 and reaches the first liquid resin r1 and the second liquid resin r2. Due to this, the first liquid resin r1 and the second liquid resin r2 are cured by the applied ultraviolet light, and become first resin R1 and second resin R2. Consequently, a protective component P including the first resin R1 and the second resin R2 is formed on the one surface (bottom surface in FIG. 18) of the wafer W (protective component formation step).

As described above, also in the protective component formation method of the present embodiment, the protective component P includes the first resin R1 having a high bonding force and the second resin R2 having a lower bonding force than the first resin R1. The first resin R1 having the high bonding force is bonded to the outer circumferential part of the one surface of the wafer W, and the second resin R2 having the low bonding force is bonded to the inside of the outer circumferential part. It is therefore possible to obtain the following effects in the same manner as in First Embodiment described above. It is possible to suppress the protective component P from being peeled off from the wafer W, when the wafer W is ground. Furthermore, it is possible to easily peel the protective component P off from the wafer W. Because no sheet S is used in the present embodiment, the sheet conveyor 7 of the protective component formation apparatus 1 shown in FIG. 1 can be omitted. Furthermore, the sheet providing step of the protective component formation method is unnecessary. A sheet S may be used to easily peel the protective component P off from the wafer W. Furthermore, a protective component P similar to that of First Embodiment may be formed by adjusting the supplied amounts of the first liquid resin r1 and the second liquid resin r2.

The application of the present invention is not limited to the embodiments described above, and various variations are of course possible within the scope of the claims and the technical ideas described in the specification and drawings.

The foregoing detailed description has been presented for the purposes of illustration and description. Many modifications and variations are possible in light of the above teaching. It is not intended to be exhaustive or to limit the subject matter described herein to the precise form disclosed. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims appended hereto.

What is claimed is:

1. A protective component formation apparatus comprising:
a spreading table on which dropped liquid resin is spread;
a holding table which is provided above the spreading table to oppose the spreading table and holds a wafer;
a liquid resin supplier which is configured to supply the liquid resin to the spreading table side and includes a first supplier configured to supply first liquid resin and a second supplier configured to supply second liquid resin having a lower bonding force than the first liquid resin;
an elevation mechanism which is configured to spread the liquid resin by moving up and down the holding table and the spreading table relative to each other in a vertical direction;
a curer which is configured to cure the liquid resin having been spread; and
a controller which is configured to supply the second liquid resin by the second supplier to a central part of the first liquid resin at least after the first liquid resin is supplied by the first supplier, to spread the first liquid resin and the second liquid resin over one surface of the wafer by the elevation mechanism, to cure the first liquid resin and the second liquid resin by the curer, to bond second resin that is the cured second liquid resin to a central part of the one surface of the wafer to be circular in shape, and to bond first resin that is the cured first liquid resin to a part outside the second resin.

2. A protective component formation method comprising a step of forming a protective component by spreading the liquid resin over the one surface of the wafer by using the protective component formation apparatus according to claim 1, and
the step of forming the protective component comprising at least:
a first liquid resin supplying step of supplying the first liquid resin to the spreading table side;
a second liquid resin supplying step of supplying the second liquid resin to a central part of the first liquid resin;
a spreading step of spreading the first liquid resin and the second liquid resin over the one surface of the wafer by moving the spreading table and the holding table toward each other in a relative manner in the vertical direction; and
a curing step of curing the first liquid resin and the second liquid resin.

3. The protective component formation method according to claim 2, further comprising
a sheet providing step of providing a sheet on the spreading table, before the first liquid resin supplying step is executed,
in the first liquid resin supplying step, the first liquid resin being supplied onto the sheet.

4. The protective component formation method according to claim 2, further comprising
a step of supplying the second liquid resin onto the spreading table, before the first liquid resin supplying step is executed,
in the first liquid resin supplying step, the first liquid resin being supplied onto the second liquid resin having been supplied onto the spreading table.

5. The protective component formation method according to claim 2, further comprising a leaving-alone step of maintaining a state in which the holding table is separated from the wafer by the elevation mechanism, after the spreading step is executed.

6. A method of manufacturing a wafer, comprising:
a protective component formation step of forming the protective component on the one surface of the wafer by the protective component formation method according to claim 2;
a first grinding step of grinding, by a grinding stone, the other surface of the wafer which is opposite to the one surface on which the protective component is formed; a protective component peeling step of peeling the protective component off from the one surface of the wafer; and
a second grinding step of grinding, by the grinding stone, the one surface of the wafer from which the protective component has been peeled off.
